(19) United States
(12) Patent Application Publication
(10) Pub. No.: US 2013/0169056 A1
(43) Pub. Date: Jul. 4, 2013

(54) MULTI-MODULE INVERTERS AND CONVERTERS FOR BUILDING INTEGRABLE PHOTOVOLTAIC MODULES

(71) Applicants: Adam C. Sherman, Newark, CA (US); Jason S. Corneille, San Jose, CA (US); Todd A. Krajewski, Mountain View, CA (US)

(72) Inventors: Adam C. Sherman, Newark, CA (US); Jason S. Corneille, San Jose, CA (US); Todd A. Krajewski, Mountain View, CA (US)

(73) Assignee: MIASOLE, Santa Clara, CA (US)

(21) Appl. No.: 13/338,481

(22) Filed: Dec. 28, 2011

(51) Int. Cl. H02J 1/00; H01L 31/042

(52) U.S. Cl. 307/86; 136/244; 307/43

(57) ABSTRACT

Provided are multi-module inverters and/or converters for connecting to a set of building integrable photovoltaic (BIPV) modules that are interconnected in series and arranged into photovoltaic arrays on building structures. Outputs from multiple multi-module inverters and/or converters in one array may be combined using parallel connections and then connected to an electrical grid, standalone electrical network, or central inverter. Each set is connected to a different multi-module inverter and/or converter and may have a variable number of BIPV modules. A multi-module inverter and/or converter may be positioned within or integrated into one of the BIPV modules or attached to a building structure supporting the array. In certain embodiments, a multi-module inverter and/or converter is installed in a ventilation channel on the back side of a module. A multi-module inverter and/or converter may be also integrated into an electrical routing structure connected to one of the BIPV modules.

### BACKGROUND

Photovoltaic modules are widely used for electricity generation. Multiple modules may be arranged into photovoltaic arrays used to convert solar energy into electricity by the photovoltaic effect. Arrays can be installed on building structures, such as rooftops, and are used to provide electricity to the buildings and to the general electrical grid.

### SUMMARY

Provided are multi-module inverters and/or converters for connecting to a set of building integrable photovoltaic (BIPV) modules that are interconnected in series and arranged into photovoltaic arrays on building structures. Outputs from multiple multi-module inverters and/or converters in one array may be combined using parallel connections and then connected to an electrical grid, standalone electrical network, or central inverter. Each set may be connected to a different multi-module inverter and/or converter and may have a variable number of BIPV modules. A multi-module inverter and/or converter may be positioned within or integrated into one of the BIPV modules or attached to a building structure supporting the array. In certain embodiments, a multi-module inverter and/or converter is installed in a ventilation channel on the back side of a module. A multi-module inverter and/or converter may be also integrated into an electrical routing structure connected to one of the BIPV modules.

In certain embodiments, a photovoltaic array includes a first photovoltaic string and second photovoltaic string. The first photovoltaic string includes a first set of multiple BIPV modules interconnected in series. It also includes a first multi-module inverter having input leads connected to the first set of BIPV modules. The second photovoltaic string includes a second set of multiple BIPV modules interconnected in series. The second string also includes a separate multi-module inverter (i.e., the second multi-module inverter) having input leads connected to the second set of BIPV modules. Output leads of the first multi-module inverter are interconnected in parallel with output leads of the second multi-module inverter. These interconnected output leads provide a combined power output from the first and second photovoltaic strings.

In certain embodiments, the first set has more BIPV modules than the second set. In these embodiments, the same type of multi-module inverters may be used for both sets. A multi-module inverter may accommodate a different number of BIPV modules in a set. For example, a number of BIPV modules in a set may vary between five and thirty modules. Various considerations for designing a set and determining a number of BIOV modules in the set are described below.

In certain embodiments, at least a portion of the first multi-module inverter is positioned within a moisture flap portion of a BIPV module in the first set. For example, the first multi-module inverter or a portion thereof may be positioned in a ventilation channel of the BIPV module or, more specifically, in the ventilation channel formed on a back side of the moisture flap portion of the BIPV module. The first multi-module inverter and/or second multi-module inverter may include cooling fins extending into the ventilation channel of the moisture flap portion.

In certain embodiments, the moisture flap portion is at least partially molded over the first multi-module inverter. The first multi-module inverter may provide structural support to the moisture flap portion of the BIPV module in the first set. For example, the first multi-module inverter may extend into a photovoltaic portion of the BIPV module and provide structural support to the photovoltaic portion with respect to the moisture flap portion. The first multi-module inverter may be integrated into and inseparably attached to an end BIPV module during fabrication of the end BIPV module.

In certain embodiments, the first photovoltaic string also includes a building integrable electrical routing structure, which is mechanically attached and electrically connected to an end BIPV module in the first set. The first multi-module inverter may be positioned within this routing structure. In other embodiments, the first multi-module inverter is positioned in a component of a building structure supporting the photovoltaic array. For example, the first multi-module inverter may be positioned in an attic vent or a ridge vent.

In certain embodiments, all BIPV modules in the first set are positioned in the same row of the photovoltaic array. In other embodiments, BIPV modules in the first set are positioned in two or more rows. BIPV modules of the first and second sets may be positioned in different rows and/or the same row.

The first multi-module inverter may be configured to perform maximum power point tracking (MPPT) of the first set independently of the second set. The second multi-module inverter may be configured to perform MPPT of the second set independently of the first set. The first multi-module inverter may have a power rating of at least about 250 W. In the same or other embodiments, the first multi-module inverter has a starting voltage of at least about 50 V. The first set of BIPV modules may include between about two and fifty BIPV modules.

In certain embodiments, the first string further includes a control system for diagnostics of BIPV modules in the first set. The control system may be configured to disconnect the first multi-module inverter from the first set upon detecting one or more problems with BIPV modules in the first set. The control system may be configured to disconnect one BIPV module from remaining BIPV modules in the first set while keeping the remaining BIPV modules interconnected in series and connected to the first multi-module inverter. The control system may be integrated into the first multi-module inverter.

Provided also is a BIPV module including a photovoltaic portion, moisture flap portion, two or more ventilation ribs, and multi-module inverter. The photovoltaic portion includes one or more photovoltaic cells. The moisture flap portion is attached to the photovoltaic portion such that the photovoltaic portion and moisture flap portion form a back side of the BIPV module. The two or more ventilation ribs are attached to and extending from the back side of the BIPV module. The multi-module inverter is positioned in between two or more ribs and attached to the back side of the BIPV module.

Provided is a photovoltaic array including a first photovoltaic string and second photovoltaic string. The first photovoltaic string includes a first set of multiple BIPV modules interconnected in series. The first photovoltaic string also includes a first multi-module converter having input leads connected to the first set. This converter is designed to convert a DC voltage output of the first set into a stable DC voltage output that is later combined with outputs of other converters and fed, for example, into a central converter. The second photovoltaic string includes a second set of multiple BIPV modules interconnected in series. The second photovoltaic string also includes a second multi-module converter having input leads connected to the second set. Output leads of the first multi-module converter and output leads of the second multi-module converter are interconnected in parallel and provide a combined power output from the first photovoltaic string and the second photovoltaic string.

These and other embodiments are described further below with reference to the figures.

### BRIEF DESCRIPTION OF THE DRAWINGS

FIG. 1 is a schematic cross-sectional side view of a BIPV module, in accordance with certain embodiments.

FIG. 2 is a schematic top view of a BIPV module, in accordance with certain embodiments.

FIG. 3 illustrates a subset of a photovoltaic array that includes six BIPV modules, in accordance with certain embodiments.

FIG. 4 is a schematic illustration of a photovoltaic array installed on a rooftop of a building structure, in accordance with certain embodiments.

FIG. 5 is a schematic representation of a photovoltaic module having electrically interconnected photovoltaic cells, in accordance with certain embodiments.

FIG. 6 is a schematic electrical diagram of a photovoltaic array having three BIPV modules interconnected in series, in accordance with certain embodiments.

FIG. 7 is a schematic electrical diagram of a photovoltaic array having three BIPV modules interconnected in parallel, in accordance with other embodiments.

FIGS. 8A-8C are schematic cross-sectional views of two connectors configured for interconnection with each other, in accordance with certain embodiments.

FIG. 9 is a schematic perspective view of a BIPV module, in accordance with certain embodiments.

FIG. 10A is an electrical schematic of a BIPV module, in accordance with certain embodiments.

FIG. 10B is an electrical schematic of another BIPV module having a multi-module inverter, in accordance with certain embodiments.

FIG. 11A is a schematic view of a BIPV module illustrating a multi-module inverter positioned within a ventilation channel on the back side of the module, in accordance with certain embodiments.

FIG. 11B is an expanded view of a portion of the BIPV module shown in FIG. 11A, in accordance with certain embodiments.

FIG. 12 is a schematic view of a photovoltaic array having multi-module inverters positioned within electrical routing structures that are provided at the end of each row, in accordance with certain embodiments.

### DETAILED DESCRIPTION OF EXAMPLE EMBODIMENTS

A photovoltaic array typically has one or more inverters for converting a variable direct current (DC) output of its photovoltaic modules into a utility frequency alternating current (AC) having a stable predetermined voltage and frequency. The output from these inverters may then be fed into an electrical grid or used by an off-grid electrical network. In addition to inverting and stabilizing voltage, inverters may be configured for maximum power point tracking (MPPT) and anti-islanding protection. MPPT is a technique used to maximize power output from a photovoltaic array. It involves adjusting electrical loads based on non-linear output efficiencies of the photovoltaic modules in the array. Non-linear output efficiencies are often expressed as current-voltage (I-V) curves. To determine and set an optimal load, the technique also involves sampling outputs of the modules and, based on these outputs, adjusting resistance to change the operating regime of the modules. The outputs of modules tend to vary with environmental conditions, such as the temperatures of the modules and their light exposure. Therefore, different conditions may require different load settings to achieve maximum output. Anti-islanding protection may be used when an array or, more specifically, its inverters are tied to the grid. The anti-islanding technique prevents an inverter from being confused by various load circuits that resonate at the frequency of the utility grid even after the grid becomes inactive. To avoid this confusion, the inverter may be configured to inject small pulses that are slightly out of phase with the grid system to cancel any stray resonances remaining in the circuit.

At present, most photovoltaic modules available on the market are panel-type modules. These modules are rather large and designed to produce at least 200-300 Watts of power per module. When installed on building structures, these modules can be positioned on special mounting hardware above the exterior surfaces of the building structures. Generally, there is very little, if any, contact between a panel-type module and building structure. Rather, most panel-type photovoltaic modules generally have some spacing between the modules and building structure to provide some limited access to back sides of the modules and for cooling these modules during operation. This spacing may be used for making electrical connections to the module and mounting additional components, such as inverters.

Multiple panel-type photovoltaic modules positioned on the same building structure can be connected in series to produce one or more sets of modules with a nominal voltage rating of around 300 V to 600 V DC. This voltage rating is usually limited by building and electrical codes. The power from each set is then run to a central inverter, which converts this combined power of the set into the grid-rated AC power output (e.g., 240 V AC/60 Hz in the North American market or 220 V AC/50 Hz in Europe). Considering the number of the panel-type photovoltaic modules in each set and the size of each module, a typical central inverter is rated for at least 2,000-3,000 W and has a starting voltage of about 300 V. With these ratings, central inverters require special installation by licensed electricians and are usually equipped with their own cooling systems, such as fans, and may require special installation locations and periodic maintenance.

Large central inverters, each handling a few kilowatts of power output, may help to reduce a number of electrical components in the array. At the same time, any problem of one module in the loop attached to a central inverter, such as a high resistance caused by manufacturing defects or temporary shading during operation, may lower the power output of other modules by potentially shifting them into less efficient operating regimes. This may have a disproportionate impact on the entire set. Large central inverters are even less applicable to BIPV modules, which may be smaller than conventional panel-type modules and grouped in larger numbers to match starting voltage requirements and to optimally use the power ratings of central inverters.

A recent trend is to equip panel-type photovoltaic modules with micro-inverters to address some of the problems listed above. Unlike central inverters that are shared by multiple panel-type modules and have high voltage and power ratings, micro-inverters are attached to each individual panel-type module and convert power output from each module separately. An array assembled from such modules has just as many micro-inverters as there are panel-type modules. The outputs of all multiple micro-inverters are then combined for various uses. Micro-inverters are typically positioned on the back sides of the panel-type modules (i.e., in the spacing between the modules and building structures) for cooling and maintenance reasons.

Micro-inverters are capable of handling about 100-200 W of power output and have a starting voltage of only 20-50 V, which are also the typical ratings of panel-type modules. The lower voltage and power ratings of micro-inverters in comparison to central inverters help to simplify various design features. For example, a micro-inverter may be used without a special forced cooling system (e.g., cooling fan) and may use less complex and generally more robust capacitors. The lower amount of heat produced by micro-inverters may be easily dissipated into the environment-particularly into the space under the panel-type module, which is well ventilated. However, having a micro-inverter on each module is still prohibitively expensive even for large-sized panel-type modules. As such, adoption of this technology is rather slow. At the same time, BIPV modules have very little space for positioning micro-inverters and generally have no structural features or options for cooling micro-inverters. For example, the power output of BIPV modules is usually at least three times less than that of conventional panel-type modules. BIPV modules need to be smaller than panel-type modules for integration with other building components, such as asphalt shingles. Furthermore, it has been found that BIPV modules operate at much higher temperatures than conventional panel-type modules and, more importantly, generally have a much larger operating temperature range. These operating conditions impact and vary non-linear output efficiencies of photovoltaic cells integrated into BIPV modules more than the same type of cells integrated into panel-type modules. Integration of BIPV modules into building structures allows little space for positioning any other components into an array without breaking the pattern and authentic appearance of the array.

BIPV modules are positioned on building structures and typically cover most of the area available for installation. Unlike panel-type modules that are installed over exterior surfaces of building structures, BIPV modules form such exterior surfaces and may be installed in a continuous fashion to provide environmental protection and aesthetic appearance. Installation areas often have obstacles, such as attic vents and roof pipes, and may have uneven shapes that may be difficult to cover with continuous rows having the same length. These issues present some challenges for interconnecting BIPV modules in comparison with panel-type modules, which are individually positioned in a disjointed fashion and cover only some available areas. Specifically, maximum roof utilization often results in having multiple segments, which have different numbers of BIPV modules. Yet when the BIPV modules are interconnected in series into sets, different sets should generally have the same number of modules to provide the same voltage and power to match an inverter's ratings. Furthermore, when too many small BIPV modules are interconnected together, some modules may interfere with the performance of others and lower the overall power output of the set.

Provided are multi-module inverters for connecting to a set of BIPV modules that are interconnected in series and arranged into photovoltaic arrays on building structures. Outputs from multiple multi-module inverters may be combined using parallel connections and fed into a central inverter of that array or, in certain embodiments, fed directly into the electrical grid or standalone electrical network. Multi-module inverters are specifically configured to operate at voltage, current, and power levels produced by typical sets of BIPV modules. For example, the voltage ratings of multi-module inverters are generally higher than ratings of the micro-inverters described above because each multi-module inverter is connected to multiple BIPV modules interconnected in series, while each micro-inverter is connected to one panel-type module. In certain embodiments, a multi-module inverter has a starting voltage of greater than about 50 V or, more specifically, at least about 100 V or even at least about 200 V. At the same time, multi-module inverters generally operate at lower electrical currents than micro-inverters or central inverters. In certain embodiments, multi-module inverters are configured to operate at an input current of less than 10 A or, more specifically, at an input current of less than 5 A or even less than 3 A. These lower current ratings result from the smaller sizes of BIPV modules in comparison to panel-type modules. Lower current ratings allow for reducing the size of multi-module inverters, even in comparison to micro-inverters, to fit the multi-module inverters into BIPV modules. Specifically, a multi-module inverter may have a relatively low thickness to fit within the low profile of BIPV modules and other components of the building structure. In certain embodiments, the thickness of a multi-module inverter is less than 0.5 inches or, more specifically, less than 0.25 inches or even less than 0.125 inches. In certain embodiments, the power ratings of multi-module inverters may be at least about 250 W or, more specifically, at least about 500 W, or even at least about 1000 W.

These ratings of multi-module inverters allow for using multiple BIPV modules per each multi-module inverter and, more specifically, for using a variable number of BIPV modules in each set connected to one inverter. The number of BIPV modules may be determined during installation of the array and may depend on the size and shape of the installation area, presence of obstacles, aesthetic considerations, and other factors. In certain embodiments, a set includes between about two and fifty BIPV modules or, more specifically, between about five and thirty BIPV modules. Using multiple BIPV modules per each inverter helps to reduce the overall cost of arrays. At the same time, limiting the number of BIPV modules in the set connected to one multi-module inverter helps to achieve better control over the modules in the set. For example, a multi-module inverter may be configured to perform MPPT on the set of BIPV modules. A number of modules in the set attached to one multi-module inverter may be also limited by safety regulations in addition to the ratings of the inverter. For example, all modules in the set may be interconnected in series, and each additional module increases the output voltage of the set/input voltage to the inverter. The voltage output of each BIPV module may also vary based on sun intensity and temperature and is usually the highest on the cold sunny day. The maximum voltage allowed in the set (or anywhere else in the array) may be limited to less than about 600 V by electrical safety regulations. In certain embodiments, the maximum voltage input to a multi-module inverter is limited to less than about 550 V or even less than about 500 V. This limitation is met by using a fewer modules in the set. For example, if a WV module is constructed to output 15.3 V, a number of BIPV modules in one set may be less than 27 to stay within the safety limit. In this example, if the same BIPV module has a power rating of 36 W, the power rating of an inverter used to support such a set should be at least 975 W.

In some embodiments, multi-module inverters may be integrated into BIPV modules. For example, a multi-module inverter may be positioned in the ventilation channel on the back side of a BIPV module or some other cavity provided within the module. The small size of the multi-module inverters also helps with positioning them within various components of the building structure supporting the photovoltaic set, such as ridge vents and attic vents. Alternatively, a multi-module inverter may be integrated into an electrical routing structure for connecting to a BIPV module, for example, at the end of each row, or it may be positioned in a dummy module. A dummy module generally has all the mechanical components of a BIPV module except for photovoltaic cells and, as such, it has additional space to accommodate a multi-module inverter. A dummy module has the same mechanical and sealing functions as a BIPV module, but does not produce any electrical power.

Each multi-module inverter in an array provides AC power output at the same voltage and frequency. In certain embodiments, multi-module inverters are configured to provide an AC output at between about 200 V and 250 V (for example, at about 220 V or at about 240 V). Multiple outputs from different multi-module inverters can then be combined using the parallel connections of their output leads, and the combined output is fed directly into the grid, a standalone electrical network, or a central inverter. The inverters' output voltages stay constant even though the power outputs of each set of BIPV module may be initially different, due to different numbers of BIPV modules in different strings and/or fluctuations during operation of the array due to shading, temperature, and/or other variations of environmental factors. In some embodiments, converting DC to AC near the set of BIPV modules improves efficiency because electrical power is transmitted from this point on at a higher voltage and, therefore, may have lower power losses.

To provide a better understanding of multi-module inverters and their features, a brief description of BIPV modules is provided below.

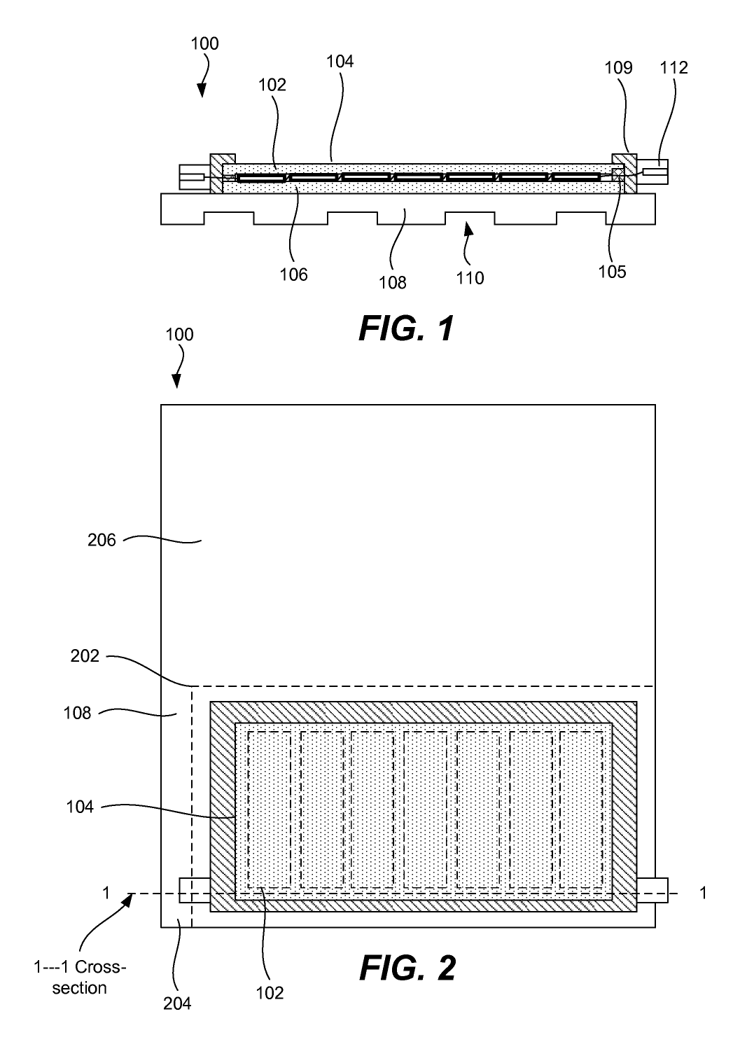

An overview BIPV modules and electrical connectors that may be used in accordance with embodiments described herein is presented below with reference to FIGS. 1-8. FIG. 1 is a schematic cross-sectional end view (line 1-1 in FIG. 2 indicates the position of this cross-section) of a BIPV module 100, in accordance with certain embodiments. BIPV module 100 may have one or more photovoltaic cells 102 that are electrically interconnected. Photovoltaic cells 102 may be interconnected in parallel, in series, or in various combinations of these. Examples of photovoltaic cells include copper indium gallium selenide (CIGS) cells, cadmium-telluride (Cd—Te) cells, amorphous silicon (a-Si) cells, micro-crystalline silicon cells, crystalline silicon (c-Si) cells, gallium arsenide multi junction cells, light adsorbing dye cells, organic polymer cells, and other types of photovoltaic cells.

Photovoltaic cell 102 has a photovoltaic layer that generates a voltage when exposed to sunlight. In certain embodiments, the photovoltaic layer includes a semiconductor junction. The photovoltaic layer may be positioned adjacent to a back conductive layer, which, in certain embodiments, is a thin layer of molybdenum, niobium, copper, and/or silver. Photovoltaic cell 102 may also include a conductive substrate, such as stainless steel foil, titanium foil, copper foil, aluminum foil, or beryllium foil. Another example includes a conductive oxide or metallic deposition over a polymer film, such as polyimide. In certain embodiments, a substrate has a thickness of between about 2 mils and 50 mils (e.g., about 10 mils), with other thicknesses also in the scope. Photovoltaic cell 102 may also include a top conductive layer. This layer typically includes one or more transparent conductive oxides (TCO), such as zinc oxide, aluminum-doped zinc oxide (AZO), indium tin oxide (ITO), and gallium doped zinc oxide. A typical thickness of a top conductive layer is between about 100 nanometers to 1,000 nanometers (for example, between about 200 nanometers and 800 nanometers), with other thicknesses within the scope.

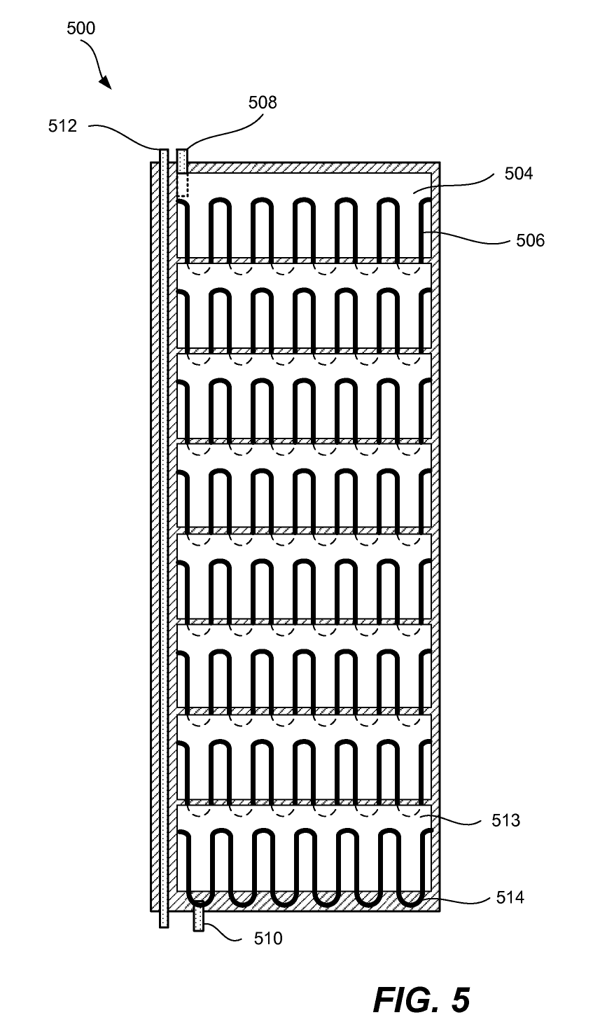

In certain embodiments, photovoltaic cells 102 are interconnected using one or more current collectors (not shown). The current collector may be attached and configured to collect electrical currents from the top conductive layer. The current collector may also provide electrical connections to adjacent cells as further described with reference to of FIG. 5, below. The current collector includes a conductive component (e.g., an electrical trace or wire) that contacts the top conductive layer (e.g., a TCO layer). The current collector may further include a top carrier film and/or a bottom carrier film, which may be made from transparent insulating materials to prevent electrical shorts with other elements of the cell and/or module. In certain embodiments, a bus bar is attached directly to the substrate of a photovoltaic cell. A bus bar may also be attached directly to the conductive component of the current collector. For example, a set of photovoltaic cells may be electrically interconnected in series with multiple current collectors (or other interconnecting wires). One bus bar may be connected to a substrate of a cell at one end of this set, while another bus bar may be connected to a current collector at another end.

Photovoltaic cells 102 may be electrically and environmentally insulated between a front sheet 104 (i.e., the light incident sheet) and a back sheet 106 (i.e., the building structure facing sheet), which may be referred to as sealing sheets. Examples of such sheets include glass, polyethylene, polyethylene terephthalate (PET), polypropylene, polybutylene, polybutylene terephthalate (PBT), polyphenylene oxide (PPO), polyphenylene sulfide (PPS) polystyrene, polycarbonates (PC), ethylene-vinyl acetate (EVA), fluoropolymers (e.g., polyvinyl fluoride (PVF), polyvinylidene fluoride (PVDF), ethylene-terafluoethylene (ETFE), fluorinated ethylene-propylene (FEP), perfluoroalkoxy (PFA) and polychlorotrifluoroethane (PCTFE)), acrylics (e.g., poly(methyl methacrylate)), silicones (e.g., silicone polyesters), and/or polyvinyl chloride (PVC), as well as multilayer laminates and co-extrusions of these materials. A typical thickness of a sealing sheet is between about 5 mils and 100 mils or, more specifically, between about 10 mils and 50 mils. In certain embodiments, a back sheet includes a metallized layer to improve water permeability characteristics of the sheet. For example, a metal foil may be positioned in between two insulating layers to form a composite back sheet. In certain embodiments, a module has an encapsulant layer positioned between one or both sheets 104, 106 and photovoltaic cells 102. Examples of encapsulant layer materials include non-olefin thermoplastic polymers or thermal polymer olefin (TPO), such as polyethylene (e.g., a linear low density polyethylene), polypropylene, polybutylene, polyethylene terephthalate (PET), polybutylene terephthalate (PBT), polystyrene, polycarbonates, fluoropolymers, acrylics, ionomers, silicones, and combinations thereof.

BIPV module 100 may also include an edge seal 105 that surrounds photovoltaic cells 102. Edge seal 105 may be used to secure front sheet 104 to back sheet 106 and/or to prevent moisture from penetrating in between these two sheets. Edge seal 105 may be made from certain organic or inorganic materials that have low inherent water vapor transmission rates (WVTR) (e.g., typically less than 1-2 g/m2/day). In certain embodiments, edge seal 105 is configured to absorb moisture from inside the module in addition to preventing moisture ingression into the module. For example, a butyl-rubber containing moisture getter or desiccant may be added to edge seal 105. In certain embodiments, a portion of edge seal 105 that contacts electrical components (e.g., bus bars) of BIPV module 100 is made from a thermally resistant polymeric material. Various examples of thermally resistant materials and RTI ratings are further described below.

BIPV module 100 may also have a support sheet 108 attached to back sheet 106. The attachment may be provided by a support edge 109, which, in certain embodiments, is a part of support sheet 108. Support sheets may be made, for example, from rigid polymer materials such as polyethylene terephthalate (e.g., RYNITE® available from Du Pont in Wilmington, Del.), polybutylene terephthalate (e.g., crastin® also available from Du Pont), polyphenylene sulfide (e.g., ryton® available from Chevron Phillips in The Woodlands, Tex.), polyamide (e.g., zytel® available from DuPont), polycarbonate, and polypropylene. In other embodiments, support sheet 108 may be attached to back sheet 106 without a separate support edge 109 or other separate supporting element. For example, support sheet 108 and back sheet 106 may be laminated together, or support sheet 108 may be formed (e.g., by injection molding) over back sheet 106. In other embodiments, back sheet 106 serves as a support sheet 108. In this case, the same element used to seal photovoltaic cells 102 may be positioned over and contact a roof structure (not shown). Support sheet 108 may have one or more ventilation channels 110 to allow for air to flow between BIPV module 100 and a building surface (e.g., a roof-deck or a water resistant underlayment/membrane on top of the roof deck). Ventilation channels 110 may be used for cooling BIPV module 100 during its operation. For example, it has been found that each 1° C. of heating from an optimal operating temperature of a typical Copper indium gallium (di)selenide CIGS cell causes an efficiency loss of about 0.33% to 0.5%.

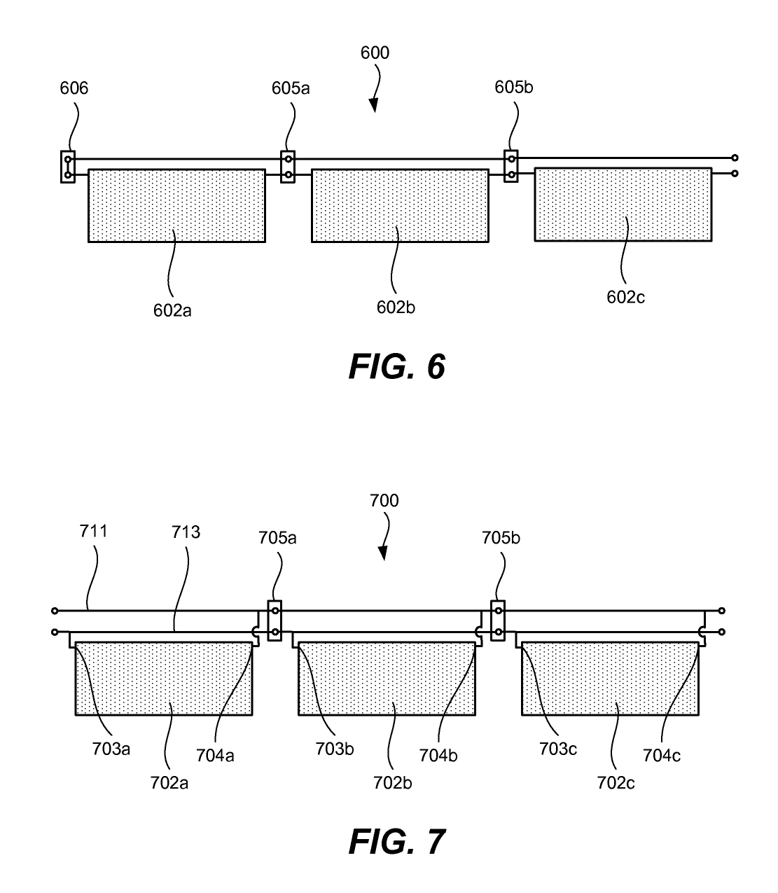

BIPV module 100 has one or more electrical connectors 112 for electrically connecting BIPV module 100 to other BIPV modules and array components, such as an inverter and/or a battery pack. In certain embodiments, BIPV module 100 has two electrical connectors 112 positioned on opposite sides (e.g., the short or minor sides of a rectangular module) of BIPV module 100, as shown in FIGS. 1 and 2, for example. However, connectors may also be positioned on other sides as well (e.g., the long or major sides of a rectangular module). Connector position may depend on the overall arrangement of the module and/or installation and repair requirements. Each one of two electrical connectors 112 has at least one conductive element electrically connected to photovoltaic cells 102. In certain embodiments, electrical connectors 112 have additional conductive elements, which may or may not be directly connected to photovoltaic cells 102. For example, each of two electrical connectors 112 may have two conductive elements, one of which is electrically connected to photovoltaic cells 102, while the other is electrically connected to a bus bar (not shown) passing through BIPV module 100. This and other examples are described in more detail in the context of FIGS. 6 and 7. In general, regardless of the number of connectors 112 attached to BIPV module 100, at least two conductive elements of these connectors 112 are electrically connected to photovoltaic cells 102.

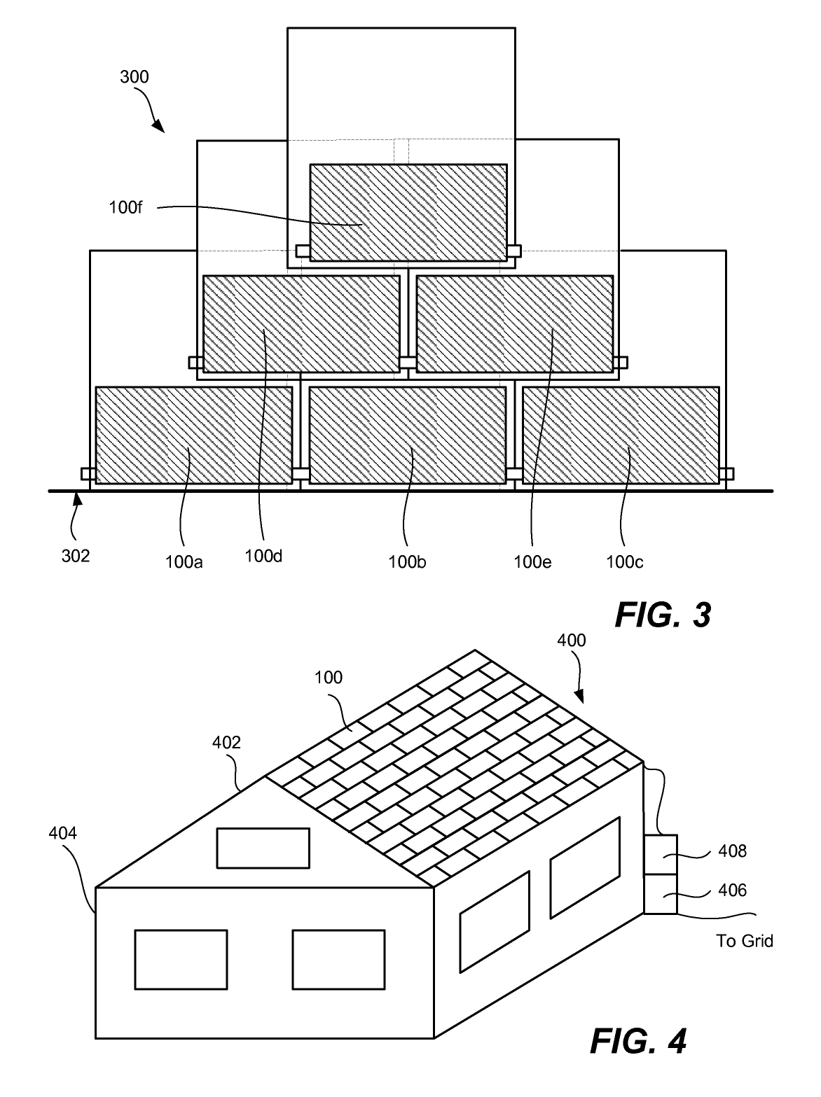

FIG. 2 is a schematic top view of BIPV module 100, in accordance with certain embodiments. Support sheet 108 is shown to have a side skirt 204 and a flap portion 206 extending beyond a photovoltaic portion 202 of BIPV module 100. Side skirt 204 is sometimes referred to as a side flap, while flap portion 206 is sometimes referred to as a top lap or a moisture flap. In certain embodiments, BIPV module 100 does not include side skirt 204. Photovoltaic portion 202 is defined as an area of BIPV module 100 that does not extend under other BIPV modules or similar building materials (e.g., roofing shingles) after installation. Photovoltaic portion 202 includes photovoltaic cells 102. Generally, it is desirable to maximize the ratio of the exposed area of photovoltaic cells 102 to photovoltaic portion 202 in order to maximize the “working area” of BIPV module 100. It should be noted that, after installation, flaps of other BIPV modules typically extend under photovoltaic portion 202. In a similar manner, after installation, side skirt 204 of BIPV module 100 may extend underneath another BIPV module positioned on the left (in the same row) of BIPV module 100, thereby creating an overlap for moisture sealing. Flap portion 206 may extend underneath one or more BIPV modules positioned above BIPV module 100. Arrangements of BIPV modules in an array will now be described in more detail with reference to FIGS. 3 and 4.

FIG. 3 illustrates a photovoltaic array 300 or, more specifically, a portion of a photovoltaic array, which includes six BIPV modules 100a-100f arranged in three different rows extending along horizontal rooflines, in accordance with certain embodiments. Installation of BIPV modules 100a-100f generally starts from a bottom roofline 302 so that the top flaps of BIPV modules 100a-100f can be overlapped with another row of BIPV modules. If a side flap is used, then the position of the side flap (i.e., a left flap or a right flap) determines which bottom corner should be the starting corner for the installation of the array. For example, if a BIPV module has a top flap and a right-side flap, then installation may start from the bottom left corner of the roof or of the photovoltaic array. Another BIPV module installed later in the same row and on the right of the initial BIPV module will overlap the side flap of the initial BIPV module. Furthermore, one or more BIPV modules installed in a row above will overlap the top flap of the initial BIPV module. This overlap of a BIPV module with a flap of another BIPV module creates a moisture barrier.

FIG. 4 is a schematic illustration of a photovoltaic array 400 installed on a rooftop 402 of a building structure 404 for protecting building structure 404 from the environment as well as producing electricity, in accordance with certain embodiments. Multiple BIPV modules 100 are shown to fully cover one side of rooftop 402 (e.g., a south side or the side that receives the most sun). In other embodiments, multiple sides of rooftop 402 are used for a photovoltaic array. Furthermore, some portions of rooftop 402 may be covered with conventional roofing materials (e.g., asphalt shingles). As such, BIPV modules 100 may also be used in combination with other roofing materials (e.g., asphalt shingles) and cover only a portion of rooftop. Generally, BIPV modules 100 may be used on steep sloped to low slope rooftops. For example, the rooftops may have a slope of at least about 2.5-to-12 or, in many embodiments, at least about 3-to-12.

Multiple BIPV modules 100 may be interconnected in series and/or in parallel with each other. For example, photovoltaic array 400 may have sets of BIPV modules 100 interconnected in series with each other (i.e., electrical connections among multiple photovoltaic modules within one set), while these sets are interconnected in parallel with each other (i.e., electrical connections among multiple sets in one array). Photovoltaic array 400 may be used to supply electricity to building structure 404 and/or to an electrical grid. In certain embodiments, photovoltaic array 400 includes an inverter 406 and/or a battery pack 408. Inverter 406 is used for converting a direct current (DC) generated by BIPV modules 100 into an alternating current (AC). Inverter 406 may be also configured to adjust a voltage provided by BIPV modules 100 or sets of BIPV modules 100 to a level that can be utilized by building structure 404 or by a power grid. In certain embodiments, inverter 406 is rated up to 600 volts DC input or even up to 1000 volts DC, and/or up to 10 kW power. Examples of inverters include a photovoltaic static inverter (e.g., BWT10240—Gridtec 10, available from Trace Technologies in Livermore, Calif.) and a string inverter (e.g. Sunny Boy®2500 available from SMA America in Grass Valley, Calif.). In certain embodiments, BIPV modules 100 may include integrated inverters (i.e., “on module” inverters). These inverters may be used in addition to or instead of external inverters. Battery pack 408 is used to balance electric power output and consumption.

FIG. 5 is a schematic representation of photovoltaic module insert 500 illustrating photovoltaic cells 504 electrically interconnected in series using interconnecting wires 506, in accordance with certain embodiments. Often individual cells 504 do not provide an adequate output voltage. For example, a typical voltage output of an individual CIGS cell is only between 0.4 V and 0.7 V. To increase voltage output, photovoltaic cells 504 may be electrically interconnected in series (for example, as shown in FIG. 5) and/or include “on module” inverters (not shown). Interconnecting wires 506 may also be used to provide uniform current distribution and collection from one or both contact layers.

As shown in FIG. 5, each pair of photovoltaic cells 504 has one interconnecting wire positioned in between the two cells and extending over a front side of one cell and over a back side of the adjacent cell. For example, a top interconnecting wire 506 in FIG. 5 extends over the front light-incident side of cell 504 and under the back side of the adjacent cell. In the figure, the interconnecting wires 506 also collect current from the TCO layer and provide uniform current distribution, and may be referred to herein as current collectors. In other embodiments, separate components are used for current collection and cell-to-cell interconnection. End cell 513 has a current collector 514 that is positioned over the light incident side of cell 513 but does not connect to another cell. Current collector 514 connects cell 513 to a bus bar 510. Another bus bar 508 may be connected directly to the substrate of the cell 504 (i.e., the back side of cell 504). In another embodiment, a bus bar may be welded to a wire or other component underlying the substrate. In the configuration shown in FIG. 5, a voltage between bus bars 508 and 510 equals a sum of all cell voltages in insert 500. Another bus bar 512 passes through insert 500 without making direct electrical connections to any photovoltaic cells 504. This bus bar 512 may be used for electrically interconnecting this insert in series without other inserts, as further described below with reference to FIG. 6. Similar current collectors/interconnecting wires may be used to interconnect individual cells or set of cells in parallel (not shown).

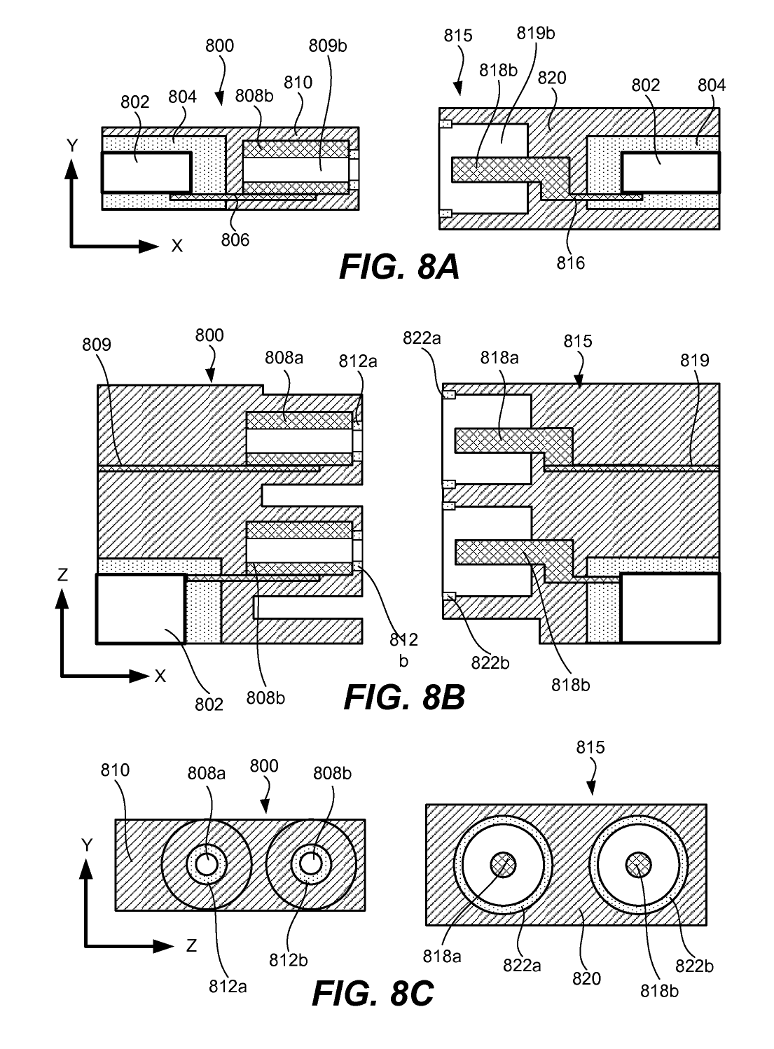

BIPV modules themselves may be interconnected in series to increase a voltage of a subset of modules or even an entire array. FIG. 6 illustrates a schematic electrical diagram of a photovoltaic array 600 having three BIPV modules 602a-602c interconnected in series using module connectors 605a, 605b, and 606, in accordance with certain embodiments. A voltage output of this three-module array 600 is a sum of the voltage outputs of the three modules 602a-602c. Each module connector 605a and 605b shown in FIG. 6 may be a combination of two module connectors of BIPV modules 602a-602c. These embodiments are further described with reference to FIGS. 8A-8C. In other words, there may be no separate components electrically interconnecting two adjacent BIPV modules, with the connection instead established by engaging two connectors installed on the two respective modules. In other embodiments, separate connector components (i.e., not integrated into or installed on BIPV modules) may be used for connecting module connectors of two adjacent modules.

Module connector 606 may be a special separate connector component that is connected to one module only. It may be used to electrically interconnect two or more conductive elements of the same module connector (e.g., to close an electrical loop in a series of connections).

Sometimes BIPV modules may need to be electrically interconnected in parallel. FIG. 7 illustrates a schematic electrical diagram of a photovoltaic array 700 having three BIPV modules 702a-702c interconnected in parallel using module connectors 705a and 705b, in accordance with certain embodiments. Each module may have two bus bars extending through the module (i.e., a “top” bus bar 711 and a “bottom” bus bar 713, as shown in FIG. 7). Top bus bars 711 of each module are connected to right electrical leads 704a, 704b, and 704c of the modules, while bottom bus bars 713 are connected to left electrical leads 703a, 703b, and 703c. A voltage between the top bus bars 711 and bottom bus bars 713 is therefore the same along the entire row of BIPV modules 702a-702c.

FIG. 8A is a schematic cross-sectional side view of two connectors 800 and 815 configured for interconnection with each other, in accordance with certain embodiments. For simplicity, the two connectors are referred to as a female connector 800 and a male connector 815. Each of the two connectors 800 and 815 is shown attached to its own photovoltaic insert, which includes photovoltaic cells 802 and one or more sheets 804. Connectors 800 and 815 include conductive elements 808b and 818b, respectively, which are shown to be electrically connected to photovoltaic cells 802 using bus bars 806 and 816, respectively.

In certain embodiments, a conductive element of one connector (e.g., conductive element 808b of female connector 800) is shaped like a socket/cavity and configured for receiving and tight fitting a corresponding conductive element of another connector (e.g., conductive element 818b of male connector 815). Specifically, conductive element 808b is shown forming a cavity 809b. This tight fitting and contact in turn establishes an electrical connection between the two conductive elements 808b and 818b. Accordingly, conductive element 818b of male connector 815 may be shaped like a pin (e.g., a round pin or a flat rectangular pin). A socket and/or a pin may have protrusions (not shown) extending towards each other (e.g., spring loaded tabs) to further minimize the electrical contact resistance by increasing the overall contact area. In addition, the contacts may be fluted to increase the likelihood of good electrical contact at multiple points (e.g., the flutes guarantee at least as many hot spot asperities of current flow as there are flutes).

In certain embodiments, connectors do not have a cavity-pin design as shown in FIGS. 8A-8C. Instead, an electrical connection may be established when two substantially flat surfaces contact each other. Conductive elements may be substantially flat or have some topography designed to increase a contact surface over the same projection boundary and/or to increase contact force at least in some areas. Examples of such surface topography features include multiple pin-type or rib-type elevations or recesses.

In certain embodiments, one or more connectors attached to a BIPV module have a “touch free” design, which means that an installer cannot accidently touch conductive elements or any other electrical elements of these connectors during handling of the BIPV module. For example, conductive elements may be positioned inside relatively narrow cavities. The openings of these cavities are too small for a finger to accidently come in to contact with the conductive elements inside the cavities. One such example is shown in FIG. 8A where male connector 815 has a cavity 819b formed by connector body 820 around its conductive pin 818b. While cavity 819b may be sufficiently small to ensure a “touch free” designed as explained above, it is still large enough to accommodate a portion of connector body 810 of female connector 800. In certain embodiments, connector bodies 810 and 820 have interlocking features (not shown) that are configured to keep the two connectors 800 and 815 connected and prevent connector body 810 from sliding outs of cavity 819b. Examples of interlocking features include latches, threads, and various recess-protrusion combinations.

FIG. 8B is schematic plan view of female connector 800 and male connector 815, in accordance with certain embodiments. Each of the connectors 800 and 815 is shown with two conductive elements, i.e., conductive elements 808a and 808b formed as sockets in connector 800 and conductive elements 818a and 818b formed as pins in connector 815. One conductive element of each connector is shown to be electrically connected to photovoltaic cells 802. Another conductive element of each of the two connectors 800 and 815 may be connected to bus bars (e.g., bus bars 809 and 819) that do not have an immediate electrical connection to photovoltaic cells 802 of their respective BIPV module (the extended electrical connection may exist by virtue of a complete electrical circuit).

As shown, conductive elements 808a and 808b may have their own designated inner seals 812a and 812b. Inner seals 812a and 812b are designed to provide more immediate protection to conductive elements 808a and 818a after connecting the two connectors 800, 815. As such, inner seals 812a and 812b are positioned near inner cavities of conductive elements 808a and 808b. The profile and dimensions of pins 818a and 818b closely correspond to that of inner seals 812a and 812b. In the same or other embodiments, connectors 800, 815 have external seals 822a and 822b. External seals 822a and 822b may be used in addition to or instead of inner seals 812a and 812b. FIG. 8C is schematic front view of female connector 800 and male connector 815, in accordance with certain embodiments. Connector pins 818a and 818b are shown to have round profiles. However, other profiles (e.g., square, rectangular) may also be used for pins 818a and 818b and conductive elements 808a and 808b.

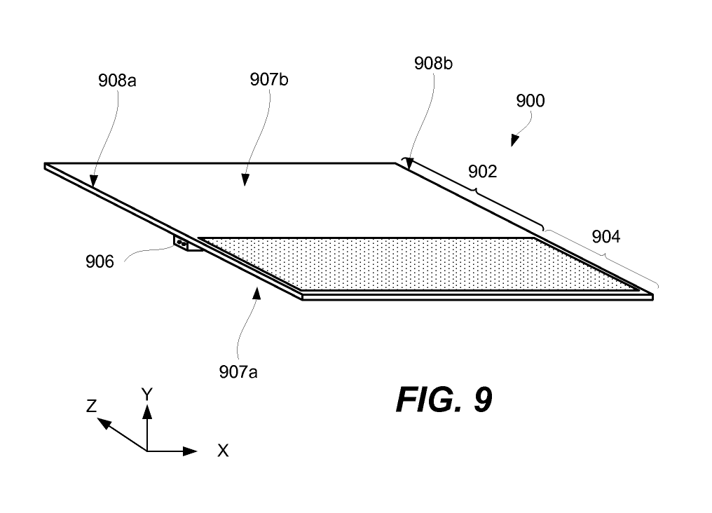

FIG. 9 is a schematic perspective view of a BIPV module 900, in accordance with certain embodiments. Module 900 includes a flap portion 902 for extending under other adjacent modules and a photovoltaic portion 904 containing one or more photovoltaic cells. Flap portion 902 is sometimes referred to as a top lap, a moisture flap, or a skirt. When module 900 is installed on a building structure, flap portion 902 may be covered by other BIPV modules or building components, such as asphalt shingles. Flap portion 902 may be cut or otherwise modified in the field without interfering with the photovoltaic cells. Flap portion 902 is generally wider than photovoltaic portion 904 in the Z direction to seal the interface between two other BIPV modules similar to the layout of asphalt shingles. Photovoltaic portion 904 remains exposed when BIPV module 900 is installed.

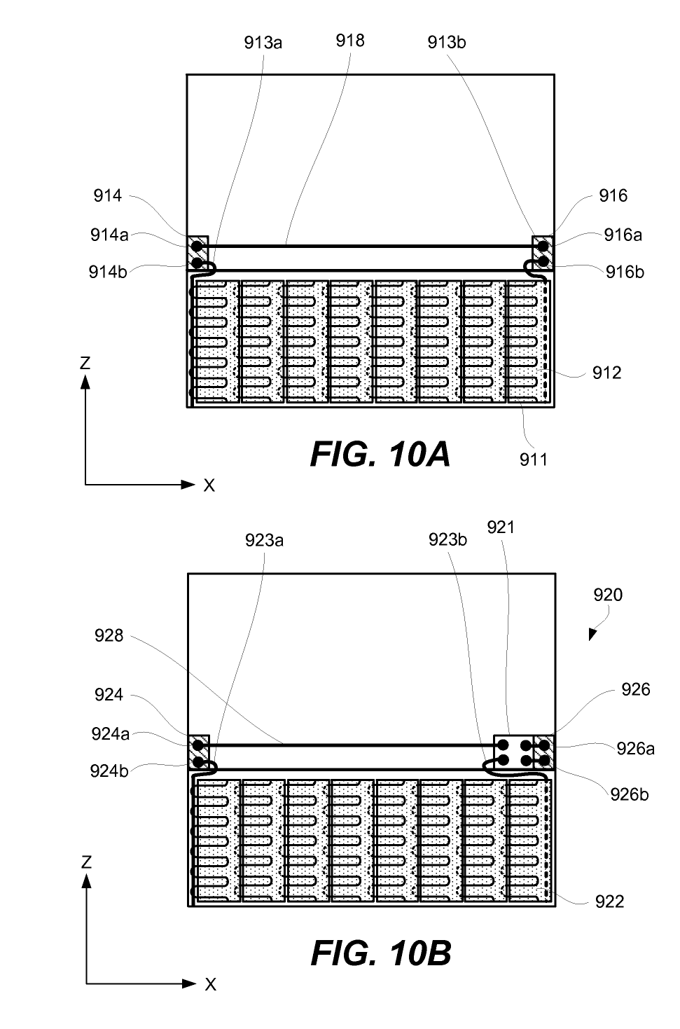

BIPV module 900 may include one of more connectors 906 positioned along edges 908a and 908b. Connectors 906 may be positioned on the back side 907a of BIPV module 900 as shown in FIG. 9. Alternatively, connector 906 may be positioned on its front side 907b. Photovoltaic portion 904 includes one or more photovoltaic cells provided on its front side 907b. The cells may be interconnected in series, in parallel, or connected according to some other scheme, such as a combination of in-series and in-parallel connections. The cells may be interconnected in such a way that only two electrical leads extend to conductive elements of connectors 906. A few examples of electrical connections within BIPV modules will now be explained in more detail with reference to FIGS. 10A and 10B.

FIG. 10A is an electrical schematic of one BIPV module, in accordance with certain embodiments. Photovoltaic cells 912 of this module are shown to be interconnected in series using wire networks 911. This interconnected set of photovoltaic cells 912 has two electrical leads 913a and 913b, each with a different polarity. Specifically, electrical lead 913a is shown to have the same polarity as the front side of the left-most photovoltaic cell. Electrical lead 913b has the same polarity as the back side of the right-most photovoltaic cell. In the example shown in FIG. 10A, electrical leads 913a and 913b are connected directly to conductive elements 914b and 916b of module connectors 914 and 916. Specifically, electrical lead 913a is connected to the bottom conductive element 914b of connector 914, while electrical lead 913b is connected to the bottom conductive element 916b of connector 916. Connector 914 may include another conductive element 914a that may be interconnected by bus bar 918 with another conductive element 916a of connector 916. In this example, conductive elements 914a and 916a, as well as bus bar 918, are parts of a return line. Connectors 914 and 916 are configured for establishing electrical connections to other, similar connectors of other BIPV modules.

FIG. 10B is an electrical schematic of another BIPV module 920 having a multi-module inverter 921 attached or integrated into BIPV module 920, in accordance with certain embodiments. Left connector 924 has connections that are similar to the ones described above with reference to FIG. 10A. Specifically, bottom conductive element 924b is connected to left lead 923a of photovoltaic cells 922, while top conductive element 924a is connected to bus bar 928. Conductive elements 926a and 926b of right connector 926 are connected to outputs of multi-module inverter 921. One input of this inverter 921 is connected to top conductive element 924a by bus bar 928. The other input of the inverter 921 is connected to a second lead 923b of photovoltaic cells 922. BIPV module 920 may be used at an end of the string module where are other BIPV modules in this string are interconnected in series and connected to left connector 924 of module 920. The electrical connections shown in FIG. 10B may be established during fabrication of BIPV module 920 with multi-module inverter 921 integrated into module 920. Alternatively, a multi-module inverter may be attached to a module in the field. The corresponding electrical connections in these embodiments are also established in the field.

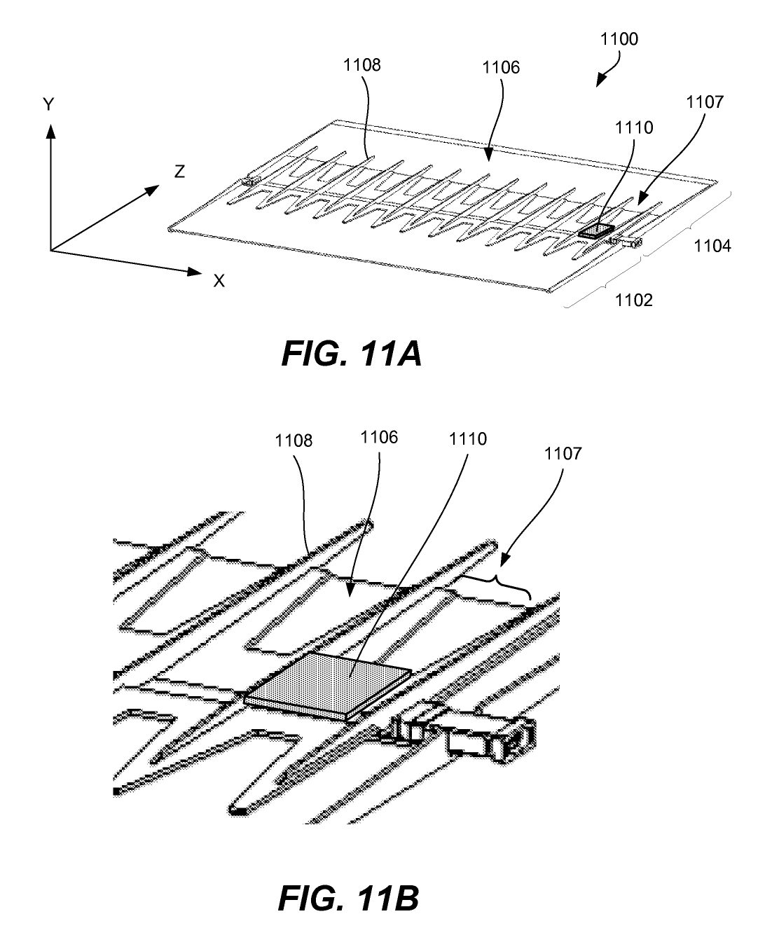

The above description addressed electrical connections within modules. Module connectors, multi-module inverters, and other electrical components of a BIPV module may be positioned in various locations of the module, such as its flap portion, its photovoltaic portion, or at the interface of the two portions. Some of these examples will now be described in more detail with reference to FIGS. 11A and 11B. Specifically, FIGS. 11A and 11B are schematic views of a BIPV module 1100 illustrating a multi-module inverter 1110 positioned in a ventilation channel 1107 of the module, in accordance with certain embodiments. One or more ventilation channels 1107 may be formed on back side 1106 by ribs 1108 that are attached to and protrude from back side 1106 of module 1100. These ribs may extend along the entire width of BIPV module in the Z direction (not shown). Alternatively, the ribs may extend only along a portion of this width as, for example, shown in FIG. 11A. Ventilation channels 1107 may be used for air circulation between back side 1106 of BIPV modules 1100 and the building structure for cooling the module 1100 during its operation. This air circulation may be also used for cooling multi-module inverter 1110. In certain embodiments, a multi-module inverter includes cooling fins provided on its exterior surface for additional heat dissipation from the inverter.

Ribs 1108 may be also used for structural support of BIPV module 1100. Specifically, ribs 1108 may extend between photovoltaic potion 1102 and flap portion 1104 of the module and support these portions with respect to each other. In certain embodiments, multi-module inverter 1110 also provides structural support to various components of BIPV module 1100. For example, multi-module inverter 1110 may be provided at the interface of photovoltaic potion 1102 and flap portion 1104, as shown in FIG. 11A, and provide support to these portions with respect to each other. Multi-module inverter 1110 may be used with or within ribs 1108. When such ribs are not present, a multi-module inverter 1110 may be integrated into photovoltaic potion 1102 and flap portion 1104. For example, these portions may be wholly or partially molded over the inverter. When ribs 1108 are provided, multi-module inverter 1110 may be integrated into the structure of these ribs. In this example, multi-module inverter 1110 may or may not be integrated into photovoltaic potion 1102 and flap portion 1104.

In certain embodiments, a multi-module inverter is positioned within the boundaries of only one portion (for example, within the boundaries of the moisture flap portion). The multi-module inverter may be integrated into this portion and provide structure support to this portion. Specifically, a moisture flap portion does not have photovoltaic cells and, therefore, provides more space for positioning the inverter.

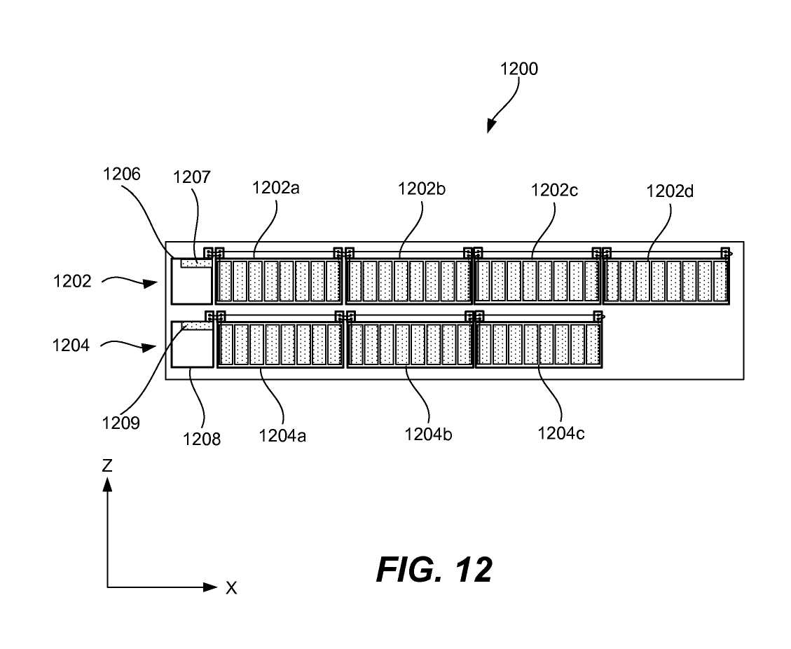

A multi-module inverter may be also positioned in various other components of the array or the building structure. For example, a multi-module inverter may be positioned within an attic vent and/or a ridge vent of the building structure used for installation of the array. Alternatively, a separate, dedicated housing may be provided on the exterior or interior surface of the building structure for positioning a multi-module inverter. Array components that may be used for positioning a multi-module inverter may include dummy cells and electrical routing structures. FIG. 12 is a schematic view of a photovoltaic array 1200 having its multi-module inverters 1207 and 1209 positioned within electrical routing structures 1206 and 1208, in accordance with certain embodiments. Photovoltaic array 1200 includes two photovoltaic strings 1202 and 1204, each forming a separate row of the array. Photovoltaic string 1202 includes four BIPV modules 1202a-1202d interconnected in series, while photovoltaic string 1204 includes three BIPV modules 1204a-1202c also interconnected in series. To route electrical power from these strings and to provide a mechanical interface between BIPV modules 1202a and 1204a of these strings and other building components (such as asphalt shingles), photovoltaic array 1200 includes two electrical routing structures 1206 and 1208. Electrical routing structure 1206 is connected to and interfaces with BIPV module 1202a, while electrical routing structure 1208 is connected to and interfaces with BIPV module 1204a. These electrical routing structures are considered to be parts of their respective strings 1202 and 1204. Electrical routing structures 1206 and 1208 may be removable from array 1200 for maintenance, upgrade, and replacement of multi-module inverters 1207 and 1209. In the same or other embodiments, multi-module inverters 1207 and 1209 are removable and replaceable from electrical routing structures 1206 and 1208 after installation of these structures, while electrical routing structures 1206 and 1208 remain in array 1200.

Each electrical routing structure may include its own multi-module inverter. Specifically, electrical routing structure 1206 includes multi-module inverter 1207. Input leads of this inverter are connected to the left connector of BIPV module 1202a. Electrical routing structure 1208 includes multi-module inverter 1209, which has input electrical leads connected to the left connector of BIPV module 1204a. All multi-module inverters in one array may be the same regardless of the number of BIPV modules connected to each inverter. Alternatively, multi-module inverters may differ and may be selected based on specific characteristics of the photovoltaic string connected to each one of these inverters. In certain embodiments, all multi-module inverters in the array provide electrical power output at substantially the same voltage and frequency. Their output leads may be interconnected in parallel for supplying power to a grid, local electrical network, or central inverter.

In certain embodiments, a set of interconnected BIPV modules also includes a control system for performing diagnostics of the modules in the set. The control system may be integrated into the multi-module inverter or be a standalone component. The control system may be configured to disconnect the entire set from the array, for example, by disconnecting the inverter from the BIPV module or breaking a connection between two interconnected modules in the set. Alternatively, only the one or more BIPV modules having problems may be disconnected in the set while the remaining modules are connected to the rest of the array through the multi-module inverter. Disconnection may be performed upon detecting a problem with the BIPV modules in the set. The control system may be monitoring the overall resistance of the set, power output, temperature, and/or other characteristics of the set or individual modules in the set.

The above description pertains to multi-module inverters, which are used for converting DC input from one or more BIPV modules arranged into a photovoltaic string into an AC output. Instead of using multi-module inverters, such a string may be connected to a multi-module converter, which converts a DC input into DC output. One or more DC outputs from these multi-module converters may then be fed into and combined at a central inverter for converting this combined DC input into a combined AC output, which may have utility frequency. In other embodiments, one or more DC outputs from multi-module inverters may be used as a combined DC power without converting it into AC. Having multiple multi-module converters instead of one central inverter or central converter allows for greater flexibility in designing BIPV strings, which include managing around roof obstructions, roof shapes, penetration locations and dealing with shading issues.

Similar to multi-module inverters, multi-module converters may receive variable DC input caused by variations in BIPV module performance (e.g., resulting from different light intensity throughout the day), the number of BIPV modules in the strings, and other factors described above. The DC output of these converters is stable despite variations in the input. The output may be at a higher voltage level than the input in order to reduce power losses in downstream power transmission. Specifically, a higher voltage output may be used to reduce the wire cross-sectional area and allow for using higher gauge wires for the downstream power transmission. Use of multi-module converters may help to lower a string's voltage levels by having, for example, fewer BIPV modules in a string for safety, peak efficiency, and performance uniformity reasons.

In certain embodiments, a multi-module converter has a starting voltage of less than 50 V (for example, about 30 V). In the same or other embodiments, a multi-module converter may have a maximum power output of less than 500 W (for examples, about 350 W). To meet these characteristics of multi-module inverters, multiple BIPV modules may be interconnected into a string (for example, in series or a combination of in series and parallel connections). Multi-module inverters may produce power output at about 240 V or some other standard utility or predetermined voltage level. Outputs of multiple inverters may then be combined using parallel connections and, in certain embodiments, collectively connected to a central inverter.

A multi-module converter used for BIPV application may be configured for handling input voltages of between about 100 V and 240 V, which are typical for BIPV strings. A typical BIPV string may have multiple BIPV modules positioned in the same row on the roof and interconnected in series with each other. The number of BIPV modules in such strings is determined by the length of the roof and of each BIPV module. The presence of obstacles and uneven roof boundaries may also impact this number. The current ratings of multi-module converters may be between about 1 A and 15 A, such as between about 2 A and 5 A. In general, voltage and power characteristics of multi-module converters may be similar to multi-module inverters described above.

Multi-module converters may be mounted in a similar way as multi-module inverters and according to various techniques described above. For example, a multi-module converter may be mounted on a back side of the moisture flap, such as in a cavity or in a ventilation channel provided on the back side of a BIPV module. In certain embodiments, a multi-module converter may be mounted into an electrical routing structure connected to one of the BIPV modules (for example, at the end of the row). It may be also installed in an attic vent and/or a ridge vent.

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses. Accordingly, the present embodiments are to be considered as illustrative and not restrictive.

What is claimed is:

1. A photovoltaic array comprising:
a first photovoltaic string comprising a first set of multiple building integrable photovoltaic modules interconnected in series, the first photovoltaic string further comprising a first multi-module inverter having input leads connected to the first set; and
a second photovoltaic string comprising a second set of multiple building integrable photovoltaic modules interconnected in series, the second photovoltaic string further comprising a second multi-module inverter having input leads connected to the second set,
wherein output leads of the first multi-module inverter and output leads of the second multi-module inverter are interconnected in parallel and provide a combined power output from the first photovoltaic string and the second photovoltaic string.

2. The photovoltaic array of claim 1, wherein the first set has more multiple building integrable photovoltaic modules than the second set.

3. The photovoltaic array of claim 1, wherein at least a portion of the first multi-module inverter is positioned within a moisture flap portion of a building integrable photovoltaic module in the first set.

4. The photovoltaic array of claim 3, wherein at least the portion of the first multi-module inverter is positioned in a ventilation channel formed on a back side of the moisture flap portion of the building integrable photovoltaic module in the first set.

5. The photovoltaic array of claim 4, wherein the first multi-module inverter comprises cooling fins extending into the ventilation channel of the moisture flap portion.

6. The photovoltaic array of claim 3, wherein the moisture flap portion is at least partially molded over the first multi-module inverter.

7. The photovoltaic array of claim 3, wherein the first multi-module inverter provides structural support to the moisture flap portion of the building integrable photovoltaic module in the first set.

8. The photovoltaic array of claim 7, wherein the first multi-module inverter extends into a photovoltaic portion of the building integrable photovoltaic module and provides structural support to the photovoltaic portion with respect to the moisture flap portion.

9. The photovoltaic array of claim 1, wherein the first multi-module inverter is integrated into and inseparably attached to an end building integrable photovoltaic module during fabrication of the end building integrable photovoltaic module.

10. The photovoltaic array of claim 1, wherein the first photovoltaic string further comprises a building integrable electrical routing structure mechanically attached and electrically connected to an end building integrable photovoltaic module in the first set; and
wherein the first multi-module inverter is positioned within the building integrable electrical routing structure.

11. The photovoltaic array of claim 1, wherein the first multi-module inverter is positioned in a component of a building structure supporting the photovoltaic array, wherein the component is selected from the group consisting of an attic vent and a ridge vent.

12. The photovoltaic array of claim 1, wherein all building integrable photovoltaic modules in the first set are positioned in the same row of the photovoltaic array.

13. The photovoltaic array of claim 1, wherein the first multi-module inverter is configured to perform maximum power point tracking of the first set independently of the second set and wherein the second multi-module inverter is configured to perform maximum power point tracking of the second set independently of the first set.

14. The photovoltaic array of claim 1, wherein the first multi-module inverter has a power rating of at least about 250 W.

15. The photovoltaic array of claim 1, wherein the first multi-module inverter has a starting voltage of at least about 50 V.

16. The photovoltaic array of claim 1, wherein the first set comprises between about two and fifty building integrable photovoltaic modules.

17. The photovoltaic array of claim 1, wherein the first string further comprises a control system for diagnostics of building integrable photovoltaic modules in the first set.

18. The photovoltaic array of claim 17, wherein the control system is configured to disconnect the first multi-module inverter from the first set upon detecting one or more problems with building integrable photovoltaic modules in the first set.

19. The photovoltaic array of claim 17, wherein the control system is configured to disconnect one building integrable photovoltaic module from remaining building integrable photovoltaic modules in the first set while keeping the remaining building integrable photovoltaic modules interconnected in series and connected to the first multi-module inverter.

20. A building integrable photovoltaic module comprising:
a photovoltaic portion comprising one or more photovoltaic cells;
a moisture flap portion attached to the photovoltaic portion, wherein the photovoltaic portion and the moisture flap portion form a back side of the building integrable photovoltaic module;
two or more ventilation ribs attached to and extending from the back side of the building integrable photovoltaic module; and
a multi-module inverter positioned in between two or more ribs and attached to the back side of the building integrable photovoltaic module.

21. A photovoltaic array comprising:
a first photovoltaic string comprising a first set of multiple building integrable photovoltaic modules interconnected in series, the first photovoltaic string further comprising a first multi-module converter having input leads connected to the first set; and
a second photovoltaic string comprising a second set of multiple building integrable photovoltaic modules interconnected in series, the second photovoltaic string further comprising a second multi-module converter having input leads connected to the second set,
wherein output leads of the first multi-module converter and output leads of the second multi-module converter are interconnected in parallel and provide a combined power output from the first photovoltaic string and the second photovoltaic string.
